(19) United States
(12) Patent Application Publication
(10) Pub. No.: US 2025/0037979 A1
(43) Pub. Date: Jan. 30, 2025

(54) RESILIENT RELEASE LAYER FOR LITHIUM FILM TRANSFER AND ATMOSPHERIC PLASMA ASSISTED REMOVAL OF RESIDUAL RELEASE LAYER

(71) Applicant: Applied Materials, Inc., Santa Clara, CA (US)

(72) Inventors: Mina T. FARAG, Cupertino, CA (US); Terry BLUCK, Santa Clara, CA (US)

(21) Appl. No.: 18/785,552

(22) Filed: Jul. 26, 2024

Related U.S. Application Data
(60) Provisional application No. 63/529,627, filed on Jul. 28, 2023.

(51) Int. Cl. H01J 37/32

(52) U.S. Cl. CPC H01J 37/32825; H01J 37/32752; H01J 2237/334

(57) ABSTRACT

Methods and systems for transferring an alkali metal film, for example, a lithium film or a sodium film, from a flexible carrier substrate, for example, a polyethylene terephthalate (PET) substrate onto a metallic-containing substrate, for example, a copper foil, is provided. The methods and systems utilize atmospheric plasma in combination within a roll-to-roll process to facilitate the transfer of the alkali metal film while etching away residue from a release layer or reaction layer formed during high-temperature deposition of the lithium film. The resulting pristine lithium surface can then be passivated. The methods and systems are especially useful for applications in lithium-ion batteries and other energy storage devices.

### CROSS-REFERENCE TO RELATED APPLICATIONS

This application claims the benefit of U.S. Provisional Patent Application Ser. No. 63/529,627, filed Jul. 28, 2023, which is incorporated by reference herein in its entirety.

### BACKGROUND

### Field

The present disclosure generally relates to energy storage devices and methods and apparatus for manufacturing energy storage devices. More particularly, the present disclosure generally relates to methods and apparatus for processing of alkali metal surfaces incorporated in energy storage devices.

### Description of the Related Art

Rechargeable energy storage devices are currently becoming increasingly essential for many fields of everyday life. High-capacity energy storage devices incorporating alkali metals, such as lithium-ion (Li-ion) batteries, are used in a growing number of applications, including portable electronics, medical, transportation, grid-connected large energy storage, renewable energy storage, and uninterruptible power supply (UPS).

Like the heavy element homologs of the first main group, alkali metals such as lithium are characterized by a strong reactivity with a variety of substances. Lithium reacts violently with water, alcohols and other substances that contain protic hydrogen, often resulting in ignition. Lithium is unstable in air and reacts with oxygen, nitrogen and carbon dioxide. Lithium is normally handled under an inert gas atmosphere (noble gases such as argon) and the strong reactivity of lithium entails that other processing operations also be performed in an inert gas atmosphere. As a result, lithium provides several challenges when it comes to processing, storage, and transportation.

Therefore, there is a need for methods and apparatus for the deposition and processing of alkali metals used in energy storage devices.

### SUMMARY

The present disclosure generally relates to energy storage devices and methods and apparatus for manufacturing energy storage devices. More particularly, the present disclosure generally relates to methods and apparatus for processing of alkali metal surfaces incorporated in energy storage devices.

In one aspect, a plasma etching device for decontaminating a material deposited on a substrate is provided. The plasma etching device includes an etching source capable of generating radicals from at least one etching gas and a radical outlet coupled to the etching source, the radical outlet substantially facing a fresh surface of the material and capable of removing a portion of the material by directing the radicals to the fresh surface of the material.

In another aspect, a deposition apparatus is provided. The deposition apparatus may include a deposition source configured to deposit a material onto a substrate, an etching source capable of generating radicals from at least one etching gas, and a radical outlet coupled to the etching source, the radical outlet substantially facing a fresh surface of the material and capable of removing a portion of the material by directing the radicals to the fresh surface of the material.

In yet another aspect, a method for plasma etching of a material is provided. The method may include depositing the material onto a substrate via an evaporation process. The method my further include laminating the material onto a foil and subjecting the material to a plasma etching process, wherein the plasma etching process removes at least a portion of a polymer from a surface of the material. The method may further include purging a chamber with an inert gas and venting the chamber to an atmospheric pressure to produce a passivated surface on the material.

In yet another aspect, a flexible substrate processing system is provided. The system includes a pickup hub, a supply hub, and a calendering unit including a first calender roller and a second calender roller. The calendering unit is positioned downstream from the supply hub and upstream from the pickup hub. The system further includes an atmospheric plasma etching unit. The atmospheric plasma etching unit has an interior volume, the pickup hub is configured to rotate and assist in conveying a flexible substrate through the interior volume of the atmospheric plasma etching unit, the atmospheric plasma etching unit is positioned downstream from the supply hub and upstream from the pickup hub, the atmospheric plasma etching unit includes one or more plasma sources configured to generate and direct a plasma toward the flexible substrate when the flexible substrate is conveyed through the interior volume of the atmospheric plasma etching unit.

Implementations may include one or more of the following. The one or more plasma sources includes a first plasma source and a second plasma source, the first plasma source positioned to direct a plasma to a first portion of the interior volume on a first side of the flexible substrate when the flexible substrate is conveyed through the interior volume of the atmospheric plasma etching unit and the second plasma source positioned to direct a plasma to a second portion of the interior volume on a second side of the flexible substrate opposite to the first side when the flexible substrate is conveyed through the interior volume of the atmospheric plasma etching unit. The atmospheric plasma etching unit is positioned downstream from the supply hub and upstream from the calendering unit. The atmospheric plasma etching unit is positioned downstream from the calendering unit and upstream from the pickup hub. The plasma is a non-equilibrium plasma generated at atmospheric pressure. The system further includes a pressure control system fluidly coupled with the interior volume. The pressure control system maintains pressure within the interior volume at an ambient pressure. The system further includes a passivation unit positioned downstream from the atmospheric plasma etching unit and upstream from the pickup hub.

In yet another aspect, a flexible substrate processing system for transferring a film from a substrate is provided. The system include a plasma etching unit having an interior volume. The plasma etching unit includes one or more plasma sources configured to generate and direct a plasma toward a flexible substrate when the flexible substrate is conveyed through the interior volume of the plasma etching unit. The system further includes a system controller configured to cause the processing system to perform a process. The process includes conveying a flexible carrier film stack from a supply hub toward a pickup hub. The flexible carrier film stack including a flexible carrier film having an alkali metal film formed thereover and a release layer disposed in between the flexible carrier film and the alkali metal film. The process further includes contacting the flexible carrier film stack with a flexible substrate film stack, wherein the alkali metal film contacts the flexible substrate film stack, separating the flexible carrier film from the alkali metal film, and exposing the alkali metal film to the plasma to remove at least a portion of the release layer from the alkali metal film.

Implementations may include one or more of the following. The plasma is a non-equilibrium plasma generated at atmospheric pressure. The process further includes generating a plasma in the interior volume while maintaining the interior volume at an ambient pressure. The process further includes passivating a surface of the alkali metal film after exposing the alkali metal film to the plasma. The flexible carrier film is formed from a polymer material and the alkali metal film is a lithium film. The plasma is formed from oxygen-containing gas and the release layer includes a silicon-based polymer. The flexible substrate film stack includes a current collector substrate, an anode film, or an anode film formed on the current collector substrate. Contacting the flexible carrier film stack with the flexible substrate film stack includes laminating the alkali metal film to the flexible substrate film stack.

In yet another aspect, a method for transferring a film from a substrate is provided. The method includes conveying a flexible carrier film stack from a supply hub toward a pickup hub. The flexible carrier film stack including a flexible carrier film having an alkali metal film formed thereover and a release layer disposed in between the flexible carrier film and the alkali metal film. The method further includes contacting the flexible carrier film stack with a flexible substrate film stack, wherein the alkali metal film contacts the flexible substrate film stack, separating the flexible carrier film from the alkali metal film, and exposing the alkali metal film to a plasma to remove at least a portion of the release layer from the alkali metal film.

Implementations may include one or more of the following. The plasma is a non-equilibrium plasma generated at atmospheric pressure. The method further includes generating the plasma in an interior volume of a plasma etching unit while maintaining the interior volume at an ambient pressure. The method further includes passivating a surface of the alkali metal film after exposing the alkali metal film to the plasma. The flexible carrier film is formed from a polymer material and the alkali metal film is a lithium film. The plasma is formed from oxygen-containing gas and the release layer includes a silicon-based polymer. The flexible substrate film stack includes a current collector substrate, an anode film, or the anode film formed on the current collector substrate. Contacting the flexible carrier film stack with the flexible substrate film stack includes laminating the alkali metal film to the flexible substrate film stack.

In yet another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a side cross-sectional view of a transfer system incorporating one or more etching chambers and passivation chambers in accordance with one or more implementations of the present disclosure.

FIG. 2 illustrates a side cross-sectional view of one example of an atmospheric plasma chamber in accordance with one or more implementations of the present disclosure.

FIG. 3 illustrates a side cross-sectional view of another example of an atmospheric plasma chamber in accordance with one or more implementations of the present disclosure.

FIG. 4 illustrates a side cross-sectional view of one example of a passivation chamber in accordance with one or more implementations of the present disclosure.

FIG. 5 illustrates an exemplary flow chart of a method in accordance with one or more implementations of the present disclosure.

FIGS. 6A-6F illustrate views of various stages of manufacturing an anode structure according to the method of FIG. 5 in accordance with one or more implementations of the present disclosure.

FIG. 7 illustrates a schematic cross-sectional view of one implementation of a roll-to-roll (R2R) material deposition system incorporating a plasma-etching device in accordance with one or more implementations of the present disclosure.

FIG. 8 illustrates an exemplary flow chart in accordance with one or more implementations of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to energy storage devices and methods and apparatus for manufacturing energy storage devices. More particularly, the present disclosure generally relates to methods and apparatus for processing of alkali metal surfaces incorporated in energy storage devices.

Energy storage devices, for example, Li-ion batteries, generally include a positive electrode (e.g., cathode) and a negative electrode (e.g., anode) separated by a polymer separator with a liquid electrolyte. Solid-state batteries also generally include a positive electrode and a negative electrode but replace both the polymer separator and the liquid electrolyte with an ion-conducting material. Lithium may be deposited onto substrates by evaporating molten lithium or lithium vapor onto a substrate, such as a polyethylene terephthalate (PET) substrate, graphite coated copper foils, copper foils, or other suitable materials. Lithium may also be deposited onto substrates by sputtering or plating molten lithium or evaporated lithium onto a substrate, such as a graphite coated copper foils, copper foils, or other suitable materials. The substrates are maintained below a certain temperature as the lithium is being deposited on the front side of the substrates. After deposition, the lithium-coated substrate may be output for use in energy storage devices. In many cases, Lithium is deposited to a thickness of at least 1 μm to produce anodes for lithium ion batteries, although thickness of the Lithium may vary depending on the target application of the substrate. Uniformity of the Lithium may vary in a similar manner. In some cases, the lithium freshly deposited onto the substrate is especially reactive with the surrounding atmosphere. When not kept in high vacuum or within an inert atmosphere, the fresh lithium rapidly reacts with the surrounding atmosphere creating undesirable compounds on the surface of the substrate. If these undesirable compounds are not removed across the deposited lithium prior to removing the substrate from the deposition vacuum chamber, throughput of viable substrates is reduced and subsequent battery performance can be severely degraded.

Substrate independent direct transfer (SIDT) is a process for forming alkali metal anodes, for example, lithium metal anodes and pre-lithiated anodes, used in energy storage devices. In SIDT processes, alkali metal is first deposited on a carrier layer composed of one or more materials such as polyethylene terephthalate (PET), paper, or combinations thereof. The materials on the carrier layer are directly transferred to the anode for pre-lithiation or to a current collector to form a lithium metal anode on the current collector. Contaminants or residue remaining on exposed alkali metal surfaces can adversely affect resistance in the formed energy storage device. For example, during the production process, a silicon-based polymer may inadvertently contaminate the surface of the lithium film, which can negatively impact device performance. Thus, there is also a need for removing contaminants or residue present on an alkali metal surface within an SIDT process.

In one or more implementations, a method and system for transferring an alkali metal film, for example, a lithium film or a sodium film, from a flexible carrier substrate, for example, a polyethylene terephthalate (PET) substrate onto a metallic-containing substrate, for example, a copper foil, is provided. The methods and systems utilize atmospheric plasma in combination within a roll-to-roll process to facilitate the transfer of the alkali metal film while etching away residue from a release layer or reaction layer formed during high-temperature deposition of the lithium film. The resulting pristine lithium surface can then be passivated using, for example, UV/CO2 treatment. The methods and systems are especially useful for applications in lithium-ion batteries and other energy storage devices.

In one or more implementations, the system and method include preparation of a flexible carrier substrate stack including a flexible carrier substrate, for example, a PET substrate, an alkali metal film, and optionally a release layer formed in between the PET substrate and the alkali metal film. The alkali metal film is deposited using a high-temperature deposition process. Deposition of the alkali metal film may result in the formation of undesired reaction layer on the surface of the lithium film. The method and system employ a roll-to-roll transfer system to facilitate transfer of the lithium film. The system includes a feed roll that holds the flexible carrier substrate stack including the alkali metal-deposited carrier substrate and a take-up roll that collects the flexible substrate including the transferred alkali metal film, for example, the alkali metal film coated on a current collector substrate or an anode film in the case of a pre-lithiation process. The transfer system incorporates an atmospheric plasma chamber positioned between the feed roll and the take-up roll. The atmospheric plasma chamber is equipped with one or more plasma sources capable of generating a non-equilibrium plasma at atmospheric pressure. As the alkali metal-deposited carrier substrate passes through the atmospheric plasma chamber, the plasma interacts with the reaction layer on the surface of the substrate. Simultaneously, the atmospheric plasma promotes adhesion between the lithium film and the current collector or anode film during transfer. Following transfer of the alkali metal film, the current collector or anode film with the attached alkali metal film may be subjected to a passivation process. The etching treatment prepares the pristine alkali metal surfaces for subsequent processes and enhances the overall stability and performance of the alkali metal film.

In one or more implementations, the material to be treated is in the form of a continuous web wound onto a supply roll. The web passes through a series of processing zones, including the atmospheric plasma treatment zone. An atmospheric pressure plasma source is used to create the plasma. This plasma is operated at atmospheric pressure, allowing for efficient and continuous treatment of the web. The web material is continuously transported through the plasma treatment zone. As the web passes through the plasma treatment zone, the plasma chemistry, leads to etching and surface modification of the material. The ions and reactive species in the plasma bombard the surface, resulting in material removal, chemical reactions, and surface functionalization. The process parameters, including the plasma chemistry, treatment duration, and web speed, may be optimized to achieve the targeted etching and surface modification effects while ensuring uniformity and control across the entire web. Implementing atmospheric plasma etching in a roll-to-roll process enables treatment of large areas of the web material efficiently and continuously, enabling high-throughput surface modification, cleaning, or functionalization. The technique can be utilized in various industries, including flexible electronics, packaging, and textiles.

In one or more implementations, a plasma etching method for surface cleaning of a lithium film is provided. The method includes depositing a lithium film onto a carrier substrate, such as PET, via an evaporation process. The lithium film is then transferred onto a copper foil or anode material (if present) through roll-to-roll lamination manufacturing. Subsequently, the transferred lithium film is subjected to plasma etching to remove residue from a release film, for example, a silicon-based polymer, from an exposed surface of the lithium film, resulting in a clean and passivated lithium film. The method provides an efficient and selective cleaning process, ensuring enhanced performance and reliability of lithium film-based devices.

In one or more implementations, a method for forming an electrode structure is provided. The method includes depositing a lithium film onto a substrate, for example, a polymer substrate, via an evaporation process. The thickness and uniformity of the lithium film can be controlled based on the desired application. The lithium film is transferred onto a current collector substrate or anode film using roll-to-roll lamination manufacturing. This ensures efficient and large-scale production of lithium film-based devices. The transferred lithium film is exposed to a plasma etching process to remove contaminants from the exposed lithium surface, for example, silicon-based polymer contamination from the lithium surface. The plasma etching may be performed in a vacuum chamber using an etching gas, for example, oxygen or a mixture of oxygen and other gases. The etching gas reacts with the silicon-based polymer, selectively removing the silicon-based polymer from the surface of the lithium film. Various process parameters, such as RF power, gas flow rate, pressure, and temperature, may be optimized to achieve an efficient and selective plasma etching process. The etching time may be adjusted to remove the polymer contamination without causing substantial damage to the underlying lithium film. After plasma etching, the chamber may be purged with an inert gas, such as nitrogen, to remove residual etching byproducts. Subsequently, the chamber is vented to atmospheric pressure, and the clean and passivated lithium film is ready for further processing or device integration.

In one or more implementations, apparatus and methods for implementing a high vacuum (e.g., P<5⁻⁴ torr) deposition system for depositing lithium on a substrate, and following the deposition of lithium onto the substrate, a plasma etching method for surface cleaning of the lithium film disposed on the substrate is provided. When undesirable polymers form on the surface of the fresh lithium film, the plasma etching process may utilize radicals (e.g., plasma radicals) generated from an etching gas to selectively remove undesirable polymers (e.g., silicon-based polymers). Specifically, embodiments presented herein utilize the plasma radicals to target and remove undesirable substances from the deposited lithium and to passivate a lithium deposition surface soon after (e.g., immediately after) deposition. The plasma-assisted removal provides an efficient and selective cleaning process that is non-destructive to the lithium-coated substrate, ensuring enhanced performance and reliability of lithium film-based devices.

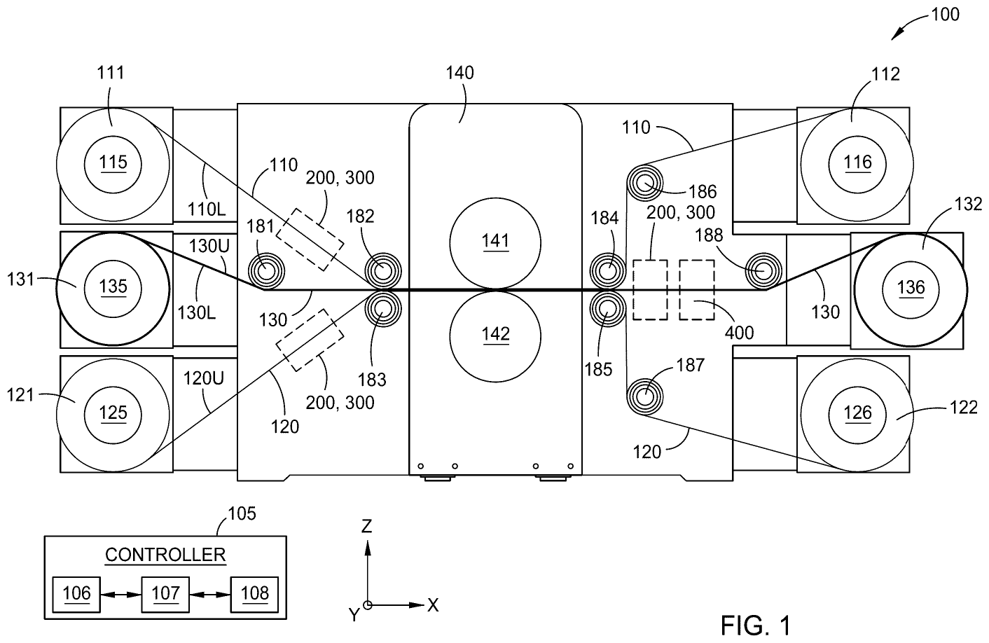

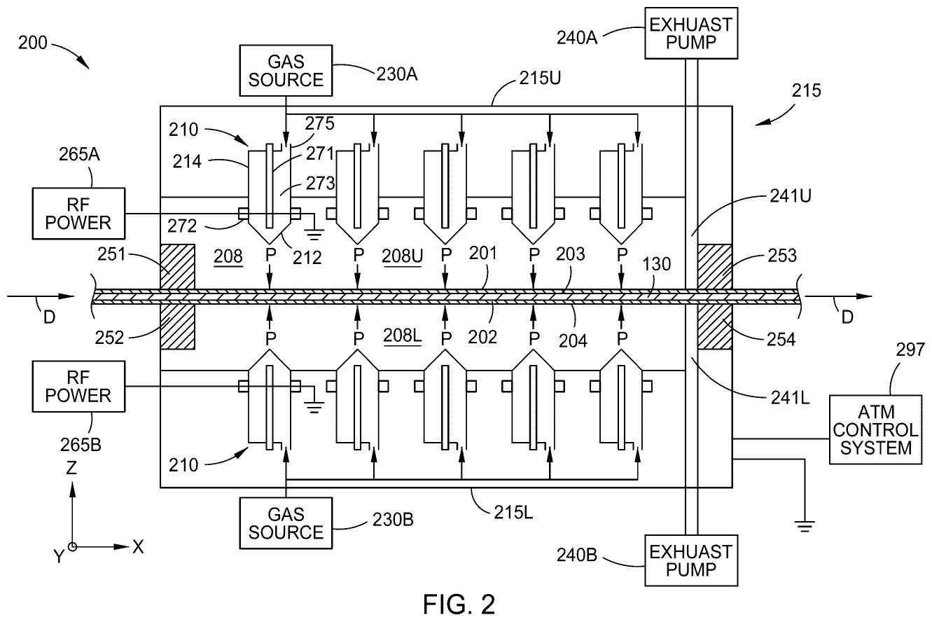

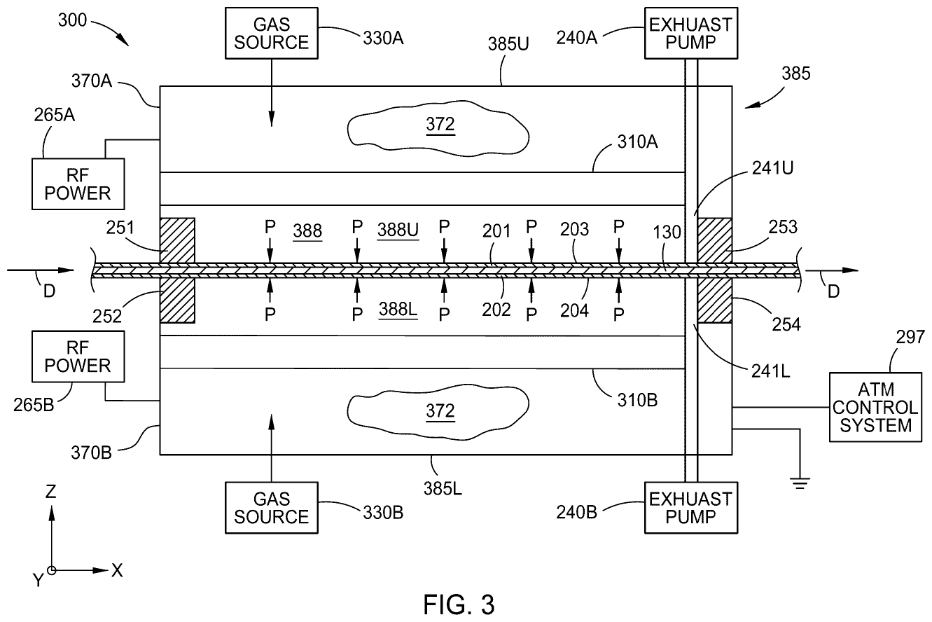

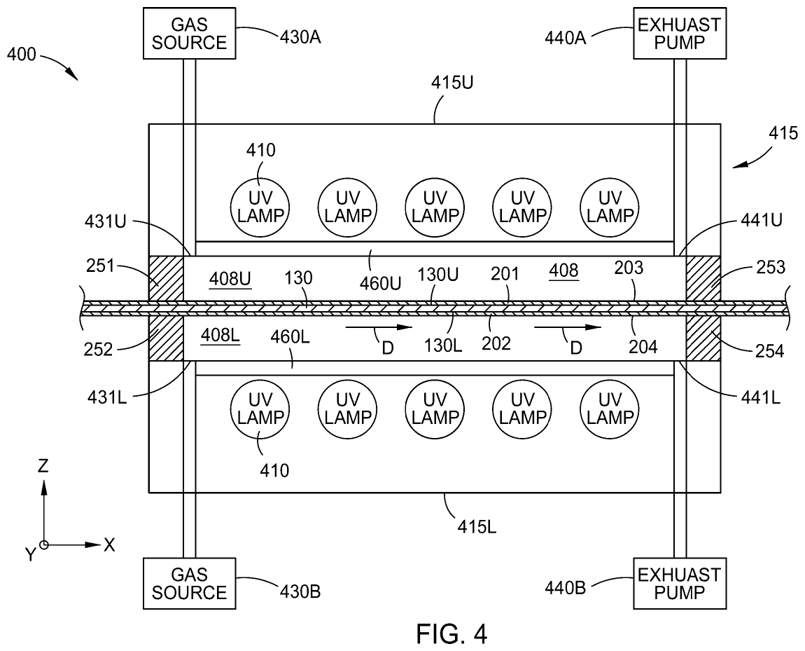

FIG. 1 illustrates a side cross-sectional view of a transfer system 100 in accordance with one or more implementations of the present disclosure. The transfer system 100 includes equipment for transferring alkali metal films on a first flexible carrier 110 and a second flexible carrier 120 to each side of a flexible substrate stack 130, so that the flexible substrate stack 130 with the alkali metal films can be used as an electrode (e.g., anode) in a lithium-ion battery. The transfer system 100 includes a calendering unit 140 to transfer the lithium films on the flexible carriers 110, 120 to the flexible substrate stack 130. The transfer system 100 further includes at least one of an atmospheric plasma etching unit 200 and/or a plasma etching unit 300 for removing contaminants or residue from an alkali metal surface and/or a passivation unit 400 for passivating the alkali metal surface. Additional details on atmospheric plasma etching unit 200 is described in reference to FIG. 2 below. Additional details on the plasma etching unit 300 is described in reference to FIG. 3 below. Additional detail on the passivation unit 400 is described below in reference to FIG. 4 below.

The transfer system 100 includes a first flexible carrier supply hub 115. A supply roll 111 of the first flexible carrier 110 is positioned on the first flexible carrier supply hub 115. In some implementations, the first flexible carrier 110 can be formed of a polymer material, such as polyethylene terephthalate (PET), polyethylene naphthalate (PEN), polyimide (PI), or combinations thereof. A alkali metal film (not shown in FIG. 1) is positioned on the lower side 110L of the first flexible carrier 110, so that the alkali metal film faces an upper surface 130U of the flexible substrate stack 130 as the first flexible carrier 110 and the flexible substrate stack 130 are conveyed through the calendering unit 140. This alkali metal film is shown as the upper lithium film 201 in FIG. 2 after being transferred to the flexible substrate stack 130. The upper surface 130U of the flexible substrate stack 130 is on an opposite side relative to a lower surface 130L of the flexible substrate stack 130. The upper surface 130U is also referred to as the first surface or the first side of the flexible substrate stack 130 while the lower surface is also referred to as the second surface or the second side of the flexible substrate stack 130.

The transfer system 100 includes a second flexible carrier supply hub 125. A supply roll 121 of the second flexible carrier 120 is positioned on the second flexible carrier supply hub 125. In some implementations, the second flexible carrier 120 can be formed of a same material (e.g., PET) as the first flexible carrier 110. An alkali metal film (not shown in FIG. 1) is positioned on the upper side 120U of the second flexible carrier 120, so that the alkali metal film faces the lower surface 130L of the flexible substrate stack 130 as the second flexible carrier 120 and the flexible substrate stack 130 are conveyed through the calendering unit 140. This alkali metal film is shown as the lithium film 202 in FIG. 2 after being transferred to the flexible substrate stack 130.

In some implementations, the alkali metal films on the first flexible carrier 110 and the second flexible carrier 120 can be formed of lithium metal, another alkali metal, for example, sodium, or an alloy including an alkali metal.

The transfer system 100 includes a flexible substrate supply hub 135. A supply roll 131 of the flexible substrate stack 130 is positioned on the flexible substrate supply hub 135. In some implementations, the flexible substrate stack 130 can be formed of one or more of copper, graphite, silicon, silicon graphite, silicon oxide graphite, silicon, metalized plastic, or other materials.

The transfer system 100 further includes the calendering unit 140. The calendering unit 140 includes a first calender roller 141 and a second calender roller 142. The first flexible carrier 110, the second flexible carrier 120, and the flexible substrate stack 130 are arranged to be conveyed along a path that extends between the first calender roller 141 and the second calender roller 142. The flexible substrate stack 130 is positioned between the first flexible carrier 110 and the second flexible carrier 120 when the first flexible carrier 110, the second flexible carrier 120, and the flexible substrate stack 130 are conveyed between the first calender roller 141 and the second calender roller 142. The calender rollers 141, 142 exert a high amount of pressure on the flexible carriers 110, 120 and the flexible substrate stack 130 that causes the alkali metal film on each of the flexible carriers 110, 120 to be transferred to the flexible substrate stack 130. In some implementations, a release layer is disposed on each of the flexible carriers 110, 120 between the corresponding flexible carrier 110, 120 and the lithium film on that flexible carrier. In some implementations, the release layer can be formed of siloxane.

The transfer system 100 includes a first flexible carrier pickup hub 116. A pickup roll 112 of the first flexible carrier 110 is positioned on the first flexible carrier pickup hub 116. The alkali metal film is no longer on the first flexible carrier 110 when the first flexible carrier 110 is wound onto the first flexible carrier pickup hub 116 because the alkali metal film previously on the first flexible carrier 110 is transferred onto the flexible substrate stack 130 by the calendering unit 140.

The transfer system 100 includes a second flexible carrier pickup hub 126. A pickup roll 122 of the second flexible carrier 120 is positioned on the second flexible carrier pickup hub 126. The alkali metal film is no longer on the second flexible carrier 120 when the second flexible carrier 120 is wound onto the second flexible carrier pickup hub 126 because the alkali metal film previously on the second flexible carrier 120 is transferred onto the flexible substrate stack 130 by the calendering unit 140.

The transfer system 100 includes a flexible substrate pickup hub 136. A pickup roll 132 of the flexible substrate stack 130 is positioned on the flexible substrate pickup hub 136. The flexible substrate stack 130 includes an alkali metal film on each of the upper surface 130U and the lower surface 130L of the flexible substrate stack 130. The alkali metal films are transferred from the respective flexible carriers 110, 120 onto the flexible substrate stack 130 by the calendering unit 140.

The transfer system 100 further includes a plurality of rollers 181-188. In some implementations, each of the rollers 181-188 can be passive rollers. The rollers 181-188 can assist in applying proper tension to and assist in changing the direction of the flexible carriers 110, 120 and the flexible substrate stack 130 during the movement of each of the flexible carriers 110, 120 and the flexible substrate stack 130 through the different portions of the transfer system 100. Some of the rollers 181-188 can also assist in moving the flexible carriers 110, 120 closer to or further away from the flexible substrate stack 130. For example, the second and third rollers 182, 183 assist in bringing the flexible carriers 110, 120 into contact with the flexible substrate stack 130 before the flexible carriers 110, 120 and the flexible substrate stack 130 are conveyed through the calendering unit 140. Additionally, the fourth and fifth rollers 184, 185 provide a location at which tension can be applied to the flexible carriers 110, 120 to peel the flexible carriers 110, 120 away from the flexible substrate stack 130. In some implementations, one or more of the rollers 181-188 can instead be a bar, such as metal bar, that can apply tension to the carrier or flexible substrate during the movement of the carrier or flexible substrate.

The transfer system 100 further includes a controller 105 for controlling processes performed by the transfer system 100. The controller 105 can be any type of controller used in an industrial setting, such as a programmable logic controller (PLC). The controller 105 includes a processor 107, a memory 106, and input/output (I/O) circuits 108. The controller 105 can further include one or more of the following components (not shown), such as one or more power supplies, clocks, communication components (e.g., network interface card), and user interfaces typically found in controllers for semiconductor equipment.

The memory 106 can include non-transitory memory. The non-transitory memory can be used to store the programs and settings described below. The memory 106 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

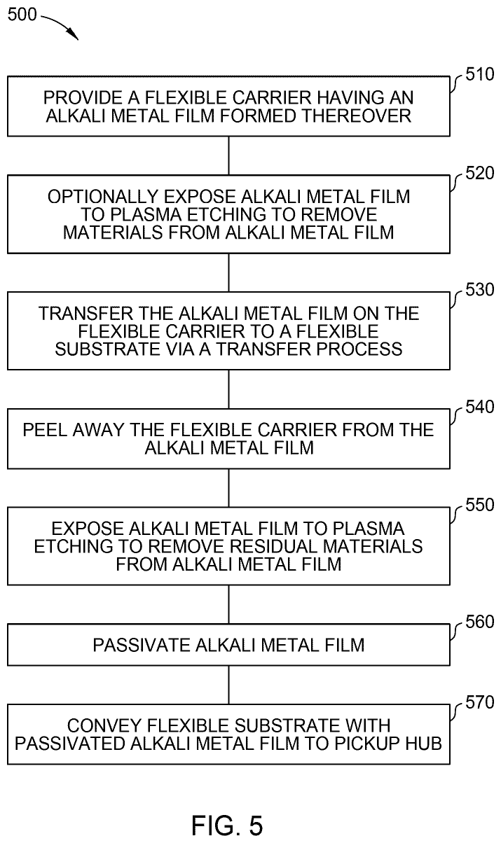

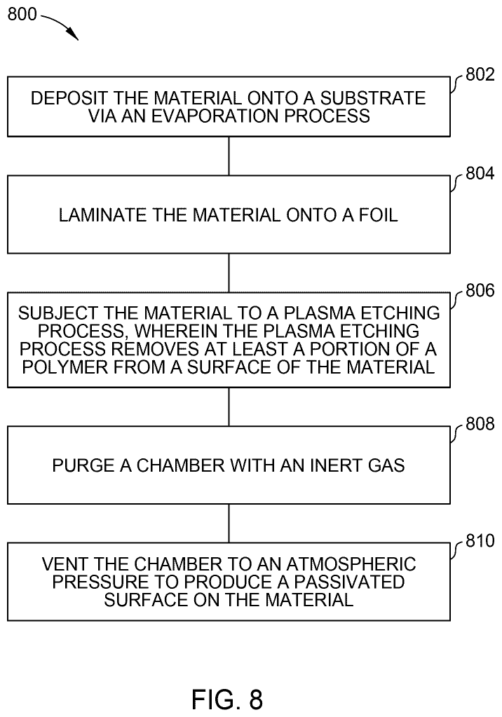

The processor 107 is configured to execute various programs stored in the memory 106, such as a program configured to execute the method 500 described in reference to FIG. 5 or the method 800 described in reference to FIG. 8. During execution of these programs, the controller 105 can communicate to I/O devices through the I/O circuits 108. For example, during execution of these programs and communication through the I/O circuits 108, the controller 105 can control outputs (e.g., the actuators connected to the different hubs and the calendering unit 140). The memory 106 can further include various operational settings used to control the transfer system 100. For example, the settings can include speed settings for the actuators connected to the hubs as well as settings to control the plasma etching unit 200 described herein.

The plasma etching units 200, 300 may be positioned to clean an exposed surface of an alkali metal, for example, the exposed surface of the alkali metal positioned on the first flexible carrier 110 or the second flexible carrier 120 prior to transfer of the alkali metal to the flexible substrate stack 130. Removing contaminants or residue from the exposed surface of the alkali metal via plasma etching prior to transfer improves adhesion of the exposed surface to the flexible substrate stack 130 during the subsequent lamination process, for example, the calendering process. For example, as shown in FIG. 1, the plasma etching units 200, 300 may be positioned downstream from the flexible substrate supply hub 135 and upstream from the calendering unit 140. The plasma etching units 200, 300 may be positioned to remove contaminants or residue from the newly exposed surfaces of the alkali metal film after the alkali metal film is transferred onto the flexible substrate stack 130. Removing residue or contaminants from the newly exposed surface of the alkali metal improves subsequent passivation of the newly exposed surface of the alkali metal, which may be performed in the passivation unit 400. For example, as shown in FIG. 1, the plasma etching units 200, 300 may be positioned downstream from the calendering unit 140 and upstream from the flexible substrate pickup hub 136. As depicted in FIG. 1, the passivation unit 400 may be positioned downstream from the calendering unit 140, downstream from the plasma etching units 200, 300 and upstream from the flexible substrate pickup hub 136.

FIG. 2 illustrates a side cross-sectional view of one example of the atmospheric plasma etching unit 200 in accordance with one or more implementations of the present disclosure. The atmospheric plasma etching unit 200 is configured to provide a jetted plasma to remove residue or contaminants from the surface of the lithium films 201, 202 prior to transfer of the lithium metal film, prior to passivation of the lithium metal film, or prior to both transfer of the lithium metal film and passivation of the lithium metal film.

The atmospheric plasma etching unit 200 includes one or more atmospheric plasma-generating units 210. In one or more implementations, which can be combined with other implementations, the plasma applicator is an atmospheric pressure plasma jet. Referring to FIG. 2, an upper alkali metal film, for example, the upper lithium film 201, is positioned on the upper surface 130U of the flexible substrate stack 130, and a lower alkali metal film (first lithium film), for example, the lower lithium film 202 (second lithium film), is positioned on the lower surface 130L of the flexible substrate stack 130. The flexible substrate stack 130 and the lithium films 201, 202 can be conveyed in a direction D through the atmospheric plasma etching unit 200 and towards the pickup hub 136. The upper lithium film 201 includes an outer surface 203. The lower lithium film 202 includes an outer surface 204. The outer surfaces 203, 204 become exposed when the first flexible carrier 110 and the second flexible carrier 120 are peeled away from the flexible substrate stack 130 after being conveyed through the calendering unit 140 and passing the rollers 184, 185 as shown in FIG. 1. In addition, after peeling away the first flexible carrier 110 and the second flexible carrier 120, a portion of the release layer may remain on the outer surfaces 203, 204. It is preferable to remove the remaining portion of the release layer from the outer surfaces 203, 204 to improve subsequent passivation of the outer surfaces 203, 204.

The atmospheric plasma etching unit 200 includes a housing 215 disposed around an interior volume 208. The housing 215 includes an upper housing 215U and a lower housing 215L. The flexible substrate stack 130 with the lithium films 201, 202 is conveyed through the interior volume 208 as the flexible substrate stack 130 is moved towards the pickup hub 136. The interior volume 208 includes an upper volume 208U above the flexible substrate stack 130 and a lower volume 208L below the flexible substrate stack 130.

In some implementations, the atmospheric plasma etching unit 200 further includes a plurality of seals 251-254. The seals 251-254 can be formed of a compressible material. The seals 251-254 can be used to maintain a separate environment in the interior volume 208 relative to the environment surrounding the atmospheric plasma etching unit 200. For example, the interior volume 208 can have different concentrations of gases as well as a different temperature and/or pressure relative to the environment surrounding the atmospheric plasma etching unit 200.

In some implementations, the seals 251-254 can be omitted and pressure differential between the interior volume 208 and the surrounding environment can be used. For example, in one implementation, the pressure in the interior volume 208 is higher than a pressure of the surrounding environment, so that nitrogen and other undesirable gases do not enter the interior volume 208 of the atmospheric plasma etching unit 200. In some implementations, an air knife, for example using an inert gas or other gas (e.g., CO₂), can be used at the entrance and exit to the interior volume 208 to prevent mixing of gases in the interior volume 208 with gases in the surrounding environment.

The first seal 251 is positioned between the upper housing 215U and the flexible substrate stack 130 at the entrance to the interior volume 208 of the atmospheric plasma etching unit 200. The second seal 252 is positioned between the lower housing 215L and the flexible substrate stack 130 at the entrance to the interior volume 208 of the atmospheric plasma etching unit 200. The third seal 253 is positioned between the upper housing 215U and the flexible substrate stack 130 at the exit from the interior volume 208 of the atmospheric plasma etching unit 200. The fourth seal 254 is positioned between the lower housing 215L and the flexible substrate stack 130 at the exit from the interior volume 208 of the atmospheric plasma etching unit 200. In one or more implementations, which can be combined with other implementations, the upper housing 215U or the lower housing 215L can be configured to move, for example in a vertical direction, so that it can be easier to position a new flexible substrate stack 130 in the interior volume 208 as well as to adjust the pressure of the seals 251-254 on the flexible substrate stack 130 or distance between the seals 251-254 and the flexible substrate stack 130 during processing.

The atmospheric plasma etching unit 200 further includes a plurality of atmospheric plasma-generating units 210 that can each generate a plasma. Five atmospheric plasma-generating units 210 are positioned in the upper housing 215U. Five atmospheric plasma-generating units 210 are positioned in the lower housing 215L. Although five atmospheric plasma-generating units 210 are shown, any number of atmospheric plasma-generating units sufficient to achieve targeted removal of contaminants or release layer residue from the outer surfaces 203, 204 of the lithium films 201, 202. Furthermore, the atmospheric plasma-generating units 210 are one example of providing a plasma to the interior volume 208 that includes the flexible substrate stack 130 and many other types of plasma-generating units can be used, such as different types of capacitively coupled plasma-generating units (e.g., different arrangements of electrodes or contacts and/or power sources other than RF energy, such as microwave energy) or inductively coupled plasma-generating units. In other implementations, a remote plasma source can be used to supply plasma to the interior volume 208 that includes the flexible substrate stack 130.

The upper housing 215U includes a gas outlet port 241U near the exit from the upper interior volume 208U. The lower housing 215L includes a gas outlet port 241L near the exit from the lower interior volume 208L. The gas outlet ports 241U, 241L can be connected to exhaust pumps 240A, 240B. In some implementations, the exhaust pumps 240A, 240B can be a single exhaust pump.

The atmospheric plasma-generating units 210 are each configured to generate a plasma P of one or more etching gases supplied from the gas sources 230A, 230B. The atmospheric plasma-generating units 210 may each be configured to generate a plasma within a high-velocity flowing gas stream. The plasma may be a jettable plasma. The plasma melts or ablates the contaminants or the residue on the alkali metal surface. The configuration (e.g., profile, shape, and/or contour) of the atmospheric plasma-generating units 210 can be in any profile or shape as needed to efficiently remove contaminants or residue from the surface of the alkali metal. In the implementation depicted in FIG. 2, the atmospheric plasma-generating units 210 may have electrodes formed in rectangular shape/configuration to efficiently remove the residue disposed on the alkali metal surface.

Each atmospheric plasma-generating units 210 includes a head 212 and a body 214. The body 214 defines an internal volume 273 and further includes a gas inlet 275. In one or more implementations, each atmospheric plasma-generating unit 210 further includes a pair of electrodes, for example, a first electrode 271 and a second electrode 272. The first electrode 271 may function as a cathode and the second electrode 272 may function as an anode. The first electrode 271 extends through the internal volume 273 defined by the body 214. The first electrode 271 may be a rod electrode. The second electrode 272 may encircle the body 214. The first electrode 271 and the second electrode 272 can be connected to one of the RF power sources 265A, 265B. The RF power sources 265A, 265B and/or the second electrode 272 can be connected to electrical ground. In one or more implementations, which can be combined with other implementations, the first electrode 271 is connected to one of the RF power sources and the second electrode 272 is connected to ground. Only one connection between the electrodes 271, 272 is shown on either side of the flexible substrate stack 130 in order to not clutter the drawing.

The gas source 230A, 230B is fluidly coupled with the body 214 and is configured to provide a gas to the internal volume 273 defined by the body 214. In one example, the gas provided to the internal volume 273 defined by the body 214 by the gas source 230A, 230B is one or more of argon (Ar), helium (He), nitrogen (N₂), oxygen (O₂), or hydrogen (H₂). A DC power of the atmospheric plasma-generating units 210 can be in a range from about 5 kV to about 15 kV, or in a range from about 10 kV to about 12 KV. The DC power of the atmospheric plasma-generating units 210 can be in a range from about 10 KHz to about 100 KHz. An RF power can be applied in a range from about watts to about 5 GHZ, or in a range from about 1 GHz to about 2 GHz. Plasma power, distance from the head 212 to the flexible substrate stack 130, and relative speed of the flexible substrate stack 130 are parameters that can be used to control residue removal.

Each of the atmospheric plasma-generating units 210 is coupled with a controller, for example, the controller 105. In operation, atmospheric plasma-generating units 210 generates a plasma “P” from a gas supplied by the gas source 230A, 230B. The atmospheric plasma-generating units 210 are positioned perpendicular to flexible substrate stack 130 and/or the travel direction “D” of the flexible substrate stack 130 to deliver a jettable plasma “P” toward the flexible substrate stack 130. The plasma “P” ablates contaminants, residual release layer materials, or both contaminants and release layer materials from the exposed alkali metal surfaces, for example outer surfaces 203, 204 of lithium films 201, 202, leaving the lithium films 201, 202 intact. In some implementations, the residual release layer is silicon-based.

The atmospheric plasma etching unit 200 may further include an atmosphere control system 297 is coupled to the housing 215. The atmosphere control system 297 includes throttle valves and pumps for controlling chamber pressure. The atmosphere control system 297 may additionally include gas sources for providing process or other gases to the interior volume 208 of the atmospheric plasma etching unit 200. In one or more implementations, the atmosphere control system 297 may assist controlling the pressure at a targeted range during the residue removal process. In one example, the pressure during the residue material removal process may be controlled at atmospheric pressure, such as at ambient pressure. Each of the atmospheric plasma-generating units 210 is coupled with a controller, for example, the controller 105.

FIG. 3 illustrates a side cross-sectional view of another example of a plasma etching unit 300 in accordance with one or more implementations of the present disclosure. The plasma etching unit 300 is configured to provide a jetted plasma to remove residue or contaminants from the surface of the lithium films 201, 202 prior to transfer of the lithium metal film, prior to passivation of the lithium metal film, or prior to both transfer of the lithium metal film and passivation of the lithium metal film.

The plasma etching unit 300 includes a housing 385 disposed around an interior volume 388. The housing 385 includes an upper housing 385U and a lower housing 385L. The plasma etching unit 300 includes an upper interior volume 388U and a lower interior volume 388L. The upper interior volume 388U is between the upper housing 385U and the upper side of the flexible substrate stack 130. The lower interior volume 388L is between the lower housing 385L and the lower side of the flexible substrate stack 130.

The plasma etching unit 300 can include one or more plasma-generating sources 370A-B for generating a plasma. Although one plasma-generating source 370A-B is shown in the in the upper housing 385U and the lower housing 385L, other implementations may include more plasma-generating sources 370A-B. Furthermore, the plasma-generating source 370A-B is one example of providing a plasma to the upper interior volume 388U and the lower interior volume 388L that includes the flexible substrate stack 130 and many other types of plasma-generating units can be used, such as different types of capacitively coupled plasma-generating units (e.g., different arrangements of electrodes and/or power sources other than RF energy, such as microwave energy) or inductively coupled plasma-generating units. In other implementations, a remote plasma source can be used to supply plasma to the interior volume 208 that includes the flexible substrate stack 130.

The plasma-generating sources 370A-B are each configured to generate a plasma “P” of one or more etching gases 372 supplied from the gas sources 330A, 330B. The configuration (e.g., profile, shape, and/or contour) of the plasma-generating sources 370A-B can be in any profile or shape as needed to efficiently remove residue from the alkali metal surface. In the implementation depicted in FIG. 3, the plasma-generating sources 370A-B may include additional components, for example, electrodes formed in rectangular shape/configuration to efficiently remove the residue disposed on the alkali metal surface.

The plasma-generating sources 370A-B generates a plasma “P” from the etching gases 372. The plasma “P” is directed toward the flexible substrate stack 130 using one or more plasma jets 310A-B. The plasma “P” ablates the contaminants or residue from the lithium films 201, 202, leaving the lithium films 201, 202 intact. In one or more implementations, the residue is silicon-based.

In one or more implementations which can be combined with other implementations, the gas sources 230A-B and the gas sources 330A-B may supply oxygen gas (O₂), a hydrogen gas (H₂), or a nitrogen gas (N₂). In one or more other implementations, the discharge gas may be a gas mixture selected from a group including noble gases, such as xenon gas (Xe), krypton gas (Kr), argon gas (Ar), neon gas (Ne), helium gas (He) and the like. In yet another implementation, the gas sources 230A-B and the gas sources 330A-B may supply a gas mixture including at least one of oxygen gas (O₂), a hydrogen gas (H₂), a nitrogen gas (N₂), a noble gas, a halogen containing gas, such as fluorine, bromine and chlorine gas, H₂O, NH₃, combinations thereof, or the like.

FIG. 4 illustrates a side cross-sectional view of one example of a passivation unit 400 in accordance with one or more implementations of the present disclosure. The passivation unit 400 may be a standalone unit. The passivation unit 400 may be used with the transfer system 100 shown in FIG. 1 according to at least one implementation of the present disclosure. In FIG. 4, the upper lithium film 201 (first lithium film) is positioned on the upper surface 130U of the flexible substrate stack 130, and the lower lithium film 202 (second lithium film) is positioned on the lower surface 130L of the flexible substrate stack 130. The flexible substrate stack 130 and the lithium films 201, 202 can be conveyed in a direction D through the passivation unit 400 and towards the flexible substrate pickup hub 136 (see FIG. 1). The upper lithium film 201 includes the outer surface 203. The lower lithium film 202 includes the outer surface 204. The outer surfaces 203, 204 become exposed when the first flexible carrier 110 and the second flexible carrier 120 are peeled away from the flexible substrate stack 130 after being conveyed through the calendering unit 140 and passing the rollers 184, 185 (see FIG. 1). The outer surfaces 203, 204 may be cleaned prior to entering the passivation unit 400 in at least one of the plasma etching units 200, 300.

In some implementations, carbon dioxide (CO₂) is provided to the corresponding passivation unit 400 along with one or more of argon (Ar), hydrogen (H₂), oxygen (O₂), and water vapor to form a passivation layer of lithium carbonate (Li₂CO₃). In other implementations, sulfur hexafluoride (SF₆) is provided to the passivation unit 400 along with one or more of argon (Ar), hydrogen (H₂), oxygen (O₂), and water vapor to form a passivation layer of lithium fluoride (LiF) or lithium sulfur hexafluoride (LiₓSF₆). Other gases that can be used to form passivation layers on a lithium surface include carbon monoxide (CO), carbon tetrafluoride (CF₄), ammonia (NH₃) as well as other oxide, fluoride, and chloride gases. The thickness of the passivation layers formed on the lithium surfaces can be from about 1 nm to about 1000 nm, such as from about 10 nm to about 500 nm. Any of the foregoing numbers can be used singly to describe an open-ended range or in combination to describe a close-ended range. In some implementations, the lithium films 201, 202 can have a thickness in a range from about 1 micron to about 100 microns, such as about 10 micron.

The passivation unit 400 includes a housing 415 disposed around an interior volume 408. The housing 415 includes an upper housing 415U and a lower housing 415L. The upper housing 415U and the lower housing 415L define an interior volume 408. The flexible substrate stack 130 with the lithium films 201, 202 is conveyed through the interior volume 408 as the flexible substrate stack 130 is moved towards the flexible substrate pickup hub 136. The interior volume 408 includes an upper interior volume 408U above the flexible substrate stack 130 and a lower interior volume 408L below the flexible substrate stack 130.

The passivation unit 400 may include seals 251-254 as described. In some implementations, the upper housing 415U or the lower housing 415L can be configured to move, for example in a vertical direction, so that it can be easier to position a new flexible substrate stack 130 in the interior volume 408 as well as to adjust the pressure of the seals 251-254 on the flexible substrate stack 130 or distance between the seals 251-254 and the flexible substrate stack 130 during processing.

The upper housing 415U includes a gas inlet port 431U near the entrance to the upper interior volume 408U and a gas outlet port 441U near the exit from the upper interior volume 408U. The lower housing 415L includes a gas inlet port 431L near the entrance to the lower interior volume 408L and a gas outlet port 441L near the exit from the lower interior volume 408L. The gas inlet ports 431U, 431L can be connected to gas sources 430A, 430B. In some implementations, the gas sources 430A, 430B can be a single gas source. The gas outlet ports 441U, 441L can be connected to exhaust pumps 440A, 440B. In some implementations, the exhaust pumps 440A, 440B can be a single exhaust pump.

The passivation unit 400 further includes a plurality of ultraviolet (UV) lamps 410. Five UV lamps 410 are positioned in the upper housing 415U. Five UV lamps 410 are positioned in the lower housing 415L. Each of the UV lamps 410 can be connected to an electrical power supply (not shown) and electrical power to the UV lamps 410 can be controlled by the controller 105 (FIG. 1). The passivation unit 400 includes an upper window 460U positioned between the UV lamps 410 in the upper housing 415U and the upper interior volume 408U. The passivation unit 400 includes a lower window 460L positioned between the UV lamps 410 in the lower housing 415L and the lower interior volume 408L. The upper window 460U and the lower window 460L can be formed of a UV-transparent material, such as quartz. In some implementations, the UV lamps 410 can be positioned in the corresponding interior volumes 408U, 408L.

The UV lamps 410 in the upper housing 415U can direct UV energy into the upper interior volume 408U to increase the rate of the passivation reactions between the upper lithium film 201 and the one or more gases (for example, CO₂) supplied to the upper interior volume 408U from the gas source 430A. Similarly, the UV lamps 410 in the lower housing 415L can direct UV energy into the lower interior volume 408L to increase the rate of the passivation reactions between the lower lithium film 202 and the one or more gases (for example, CO₂) supplied to the lower interior volume 408L from the gas source 430B. The increased rate of passivation reactions on the exposed outer surfaces 203, 204 provided by the UV energy enables a sufficient portion of the exposed outer surfaces 203, 204 of the lithium films 201, 202 to be effectively passivated before the flexible substrate stack 130 exits the passivation unit 400. In some implementations, the UV lamps 410 can emit UV radiation having a wavelength from about 100 nm to about 270 nm, such as from about 185 nm to about 254 nm. Wavelengths within these ranges can dissociate gases supplied to the passivation unit 400. For example, UV radiation within these wavelengths can split carbon dioxide (CO₂) into CO and O, which can be more reactive than the originally supplied CO₂. Similarly, these wavelengths can split water (H₂O) into H and OH, and oxygen (O₂) into O and O₃, which can also be more reactive than the originally supplied water vapor or oxygen.

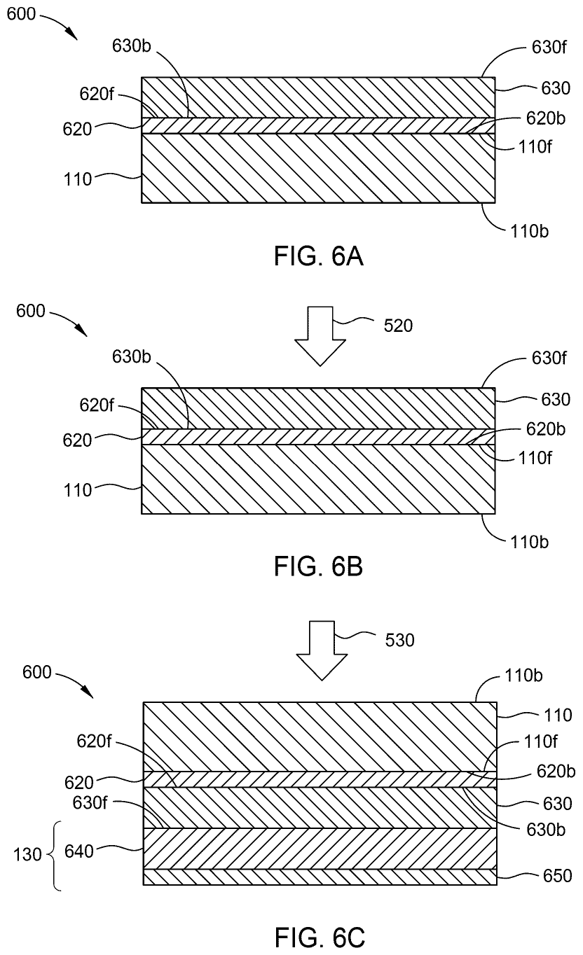

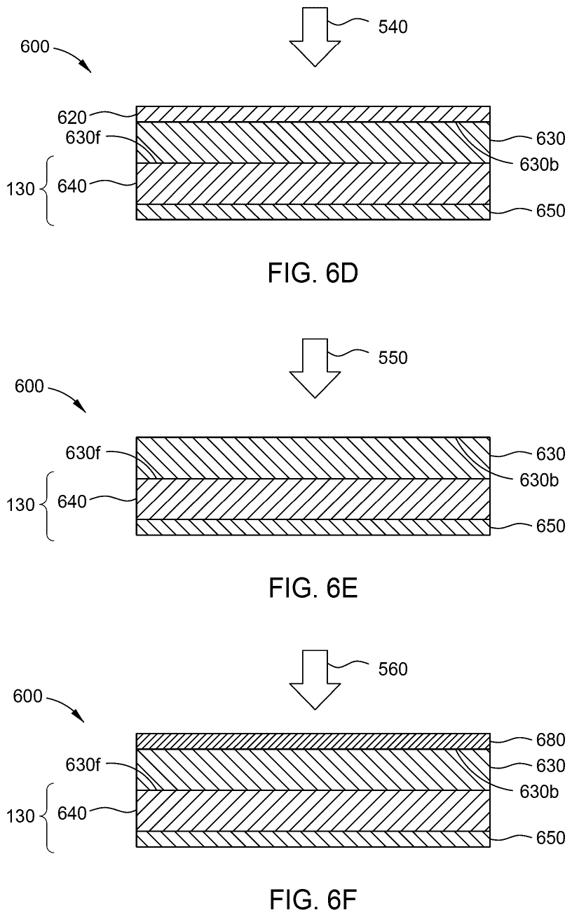

FIG. 5 illustrates a flowchart showing selected operations of a method 500 of forming an energy storage device in accordance with one or more implementations of the present disclosure. FIGS. 6A-6F illustrate views of various stages of manufacturing an energy storage device structure 600 according to the method 500 of FIG. 5 in accordance with one or more implementations of the present disclosure. Although FIGS. 6A-6F are described in relation to the method 500, it will be appreciated that the structures disclosed in FIGS. 6A-6F are not limited to the method 500, but instead may stand alone as structures independent of the method 500. Similarly, although the method 500 is described in relation to FIGS. 6A-6F, it will be appreciated that the method 500 is not limited to the structures disclosed in FIGS. 6A-6F but instead may stand alone independent of the structures disclosed in FIGS. 6A-6F. It should be understood that FIGS. 6A-6F illustrate only partial schematic views of the energy storage device structure 600, and the energy storage device structure 600 may contain any number of additional layers and/or additional materials common to energy storage devices, which are not shown for the sake of brevity. It should also be noted that although the method 500 illustrated in FIG. 5 is described sequentially, other process sequences that include one or more operations that have been omitted and/or added, and/or have been rearranged in another desirable order, fall within the scope of the implementations of the disclosure provided herein. In addition, although FIGS. 6A-6F depict a single-sided structure for the sake of brevity, the operations of the method 500 are also applicable to dual-sided structures in which the anode films, alkali metal films, and passivation films are formed on opposite sides of the flexible substrate.

Referring to FIG. 6A, at operation 510, a flexible carrier, for example, the flexible carrier 110 having an alkali metal film formed thereover is provided. The flexible carrier 110 has a frontside 110f (also referred to as a front surface) corresponding to the lower side 110L shown in FIG. 1, and a backside 110b (also referred to as a back surface) opposite the frontside 110f. The flexible carrier 110 may include any suitable material that is compatible with the targeted processing conditions. In some implementations, the flexible carrier includes a plurality of sub-layers. In one or more implementations, which can be combined with other implementations, the flexible carrier 110 can be or include, one or more layers selected from plastic, polymer materials, metallized plastic, metals, paper, multilayers thereof, or a combination thereof. Example of suitable polymer materials include polyethylene terephthalate (PET), polyethylene naphthalate (PEN), polyimide (PI), poly(methyl methacrylate) (PMMA), cellulose tri-acetate (TAC), polypropylene (PP), polyethylene (PE), polycarbonates (PC), multilayers thereof, or a combination thereof. In one or more implementations which can be combined with other implementations, the flexible carrier 110 is or includes polyethylene terephthalate (PET).

A release layer 620 is formed on the frontside 110f of the flexible carrier 110. In one or more implementations, which may be combined with other implementations, the release layer 620 and the flexible carrier 110 are pre-fabricated. The release layer 620 aids in removal of the flexible carrier 110 from the alkali metal containing film after lamination of the alkali metal containing film to the release layer 620 has a frontside 620f (also referred to as a front surface) and a backside 620b (also referred to as a back surface) opposite the frontside 620f. In one or more implementations, the release layer 620 is deposited on the frontside 110f of the flexible carrier 110 such that the backside 620b of the release layer 620 contacts the frontside 110f of the flexible carrier 110.

The release layer 620 may be or include any material suitable for releasing the anode device stack from the flexible carrier 110 during the SIDT process. The release layer 620 may be or include polymer release layers (for example, plastics, silicone, polymethylacrylate (PMA), polyethylene terephthalate (PET), fluorocarbons, polyvinylidene fluoride (PVDF), polytetrafluoroethylene (PTFE), etc.), poly(olefin sulfones), organic materials, inorganic materials, among other materials.

An alkali metal layer 630 is formed over the frontside 620f of the release layer 620. The alkali metal layer 630 may be the lithium films 201, 202 shown in FIG. 2. The alkali metal layer 630 includes a frontside 630f (also referred to as a front surface) and a backside 630b (also referred to as a back surface) opposite the frontside 630f. In some implementations, additional layers, for example solid electrolyte interface layers and interface layers may be present in between the frontside 620f of the release layer 620 and the backside 630b of the alkali metal layer 630. The alkali metal layer 630 may be or include lithium or sodium.

The frontside 630f of the alkali metal layer 630 may be exposed to atmosphere and/or other contaminants during processing. For example, exposure to oxygen may form a thin layer of lithium oxide on the frontside 630f of the alkali metal layer 630. It is desirable to remove these contaminants or residue prior to transferring the alkali metal layer 630 during the lamination transfer process of operation 520. Removal of the residue or contaminants from the frontside 630f of the alkali metal layer 630 improves adherence of the frontside 630f to an anode or current collector surface during the subsequent lamination transfer process.

Referring to FIG. 6B, optionally at operation 520, the frontside 630f of the alkali metal layer 630 is exposed to a plasma etching process to remove any residue or contaminants from the frontside 630f of the alkali metal layer 630. The plasma etching process includes exposing the frontside 630f of the alkali metal layer 630 to a plasma to remove residue or contaminants. Any plasma suitable for removal of the contaminants or residue without damaging the surface of the alkali metal layer may be used. The plasma may be an atmospheric plasma. The plasma etching process may be performed in the atmospheric plasma etching unit 200 and/or the plasma etching unit 300. For example, referring to FIG. 1, operation 520 may be performed in the atmospheric plasma etching unit 200 and/or the plasma etching unit 300 positioned downstream from the flexible carrier supply hubs 115, 125 and upstream from the calendering unit 140.

Referring to FIG. 6C, at operation 530, the alkali metal layer 630 is transferred from the flexible carrier 110 to a flexible substrate stack 130 via a lamination transfer process. The lamination transfer process may include a calendering process. The calendering process may be performed in the calendering unit 140. Operation 530 may include lamination transfer onto the flexible substrate stack 130 to form an anode stack. In some implementations, where pre-lithiation is involved, the flexible substrate stack 130 includes an anode layer 640 formed over a flexible substrate 650 and the frontside 630f of the alkali metal layer 630 contacts the anode layer 640 material formed over the flexible substrate 650. The flexible substrate 650 may be or include flexible film, such as a CPP film (i.e., a casting polypropylene film), an OPP film (i.e., an oriented polypropylene film), or a PET film (i.e., a polyethylene terephthalate film). Alternatively, the flexible substrate may be a pre-coated paper, a polypropylene (PP) film, a PEN film, a polylactic acid (PLA) film, or a PVC film. The flexible substrate 650 can be or include one or more current collectors, the current collector can include aluminum (Al), copper (Cu), zinc (Zn), nickel (Ni), cobalt (Co), manganese (Mn), chromium (Cr), stainless steel, clad materials, alloys thereof, and a combination thereof. In particular implementations, the flexible substrate 650 can be or includes copper.

The anode layer 640 may be any material compatible with a cathode film. The anode layer 640 can be or include alkali metals, alkaline earth metals, and alloys thereof. The anode layer 640 may have an energy capacity greater than or equal to 372 mAh/g, preferably ≥700 mAh/g, and most preferably ≥1000 mAh/g. The anode layer 640 may be constructed from graphite, silicon, silicon-containing graphite, silicon oxide, alkali metals, for example, alkali metal foil or an alkali metal alloy foil (e.g. lithium aluminum alloys or sodium aluminum alloys), or a mixture of an alkali metal and/or an alkali metal alloy and materials such as carbon (e.g. coke, graphite), nickel, copper, tin, indium, silicon, oxides thereof, or a combination thereof. Suitable lithium-containing metal films include lithium metal, lithium metal foil or a lithium alloy foil (e.g. lithium aluminum alloys), or a mixture of a lithium metal and/or lithium alloy and materials such as carbon (e.g. coke, graphite), nickel, copper, tin, indium, silicon, oxides thereof, or a combination thereof. Suitable sodium-containing metal films include sodium metal, sodium metal foil or a sodium alloy foil (e.g. sodium aluminum alloys), or a mixture of a sodium metal and/or sodium alloy and materials such as carbon (e.g. coke, graphite), nickel, copper, tin, indium, tellurium, silicon, oxides thereof, or a combination thereof. The anode layer 640 can include intercalation compounds containing lithium, sodium, or insertion compounds containing lithium or sodium. In one or more implementations, which can be combined with other implementations, the anode film is a lithium film or a sodium metal film. In some implementations, where the anode layer 640 includes lithium metal or sodium metal, the lithium metal or sodium metal may be deposited or transferred using the methods described herein.

Referring to FIG. 6D, at operation 540, the flexible carrier 110 and release layer 620 is peeled away from the flexible substrate stack 130 as the flexible carrier 110 is conveyed past the roller 184 as shown in FIG. 1. In one or more implementations, the release layer 620 is completely removed from the alkali metal layer 630 exposing the backside 630b of the alkali metal layer 630. However, in some implementations, at least a portion of the release layer 620 remains on the backside 630b of the alkali metal layer 630.

Referring to FIG. 6E, at operation 550, an exposed surface of the alkali metal film, for example, the backside 630b of the alkali metal layer 630 is exposed to a plasma etching process to remove any residue or contaminants remaining from the release layer 620 from the backside 630b of the alkali metal layer 630. The plasma etching process includes exposing the backside 630b of the alkali metal layer 630 to a plasma to remove residue or contaminants. Any plasma suitable for removal of the contaminants or residue without damaging the surface of the alkali metal layer may be used. The plasma may be an atmospheric plasma. The plasma etching process may be performed in the atmospheric plasma etching unit 200 and/or the plasma etching unit 300. For example, referring to FIG. 1, operation 550 may be performed in the atmospheric plasma etching unit 200 and/or the plasma etching unit 300 positioned downstream from the calendering unit 140 and upstream from the pickup hub 116.

After plasma etching, the plasma etching units 200, 300 may be purged with an inert gas to remove residual etching byproducts. The inert gas may be nitrogen or any other suitable inert gas. The plasma etching units 200, 300 is then vented to atmospheric pressure, producing a clean and passivated lithium film that is prepared for further processing or device integration.

Referring to FIG. 6F, optionally at operation 560, the exposed surface of the alkali metal film, for example, the backside 630b of the alkali metal layer 630 is exposed to a passivation process to form a passivation film 680 on the exposed surface of the alkali metal layer 630. For example, referring to FIG. 1, operation 560 may be performed in the passivation unit 400 positioned downstream from the plasma etching units 200, 300 and upstream from the pickup hub 116.

At operation 570, the flexible substrate stack 130 having the passivated alkali metal layer formed thereon is conveyed to the pickup hub 116.

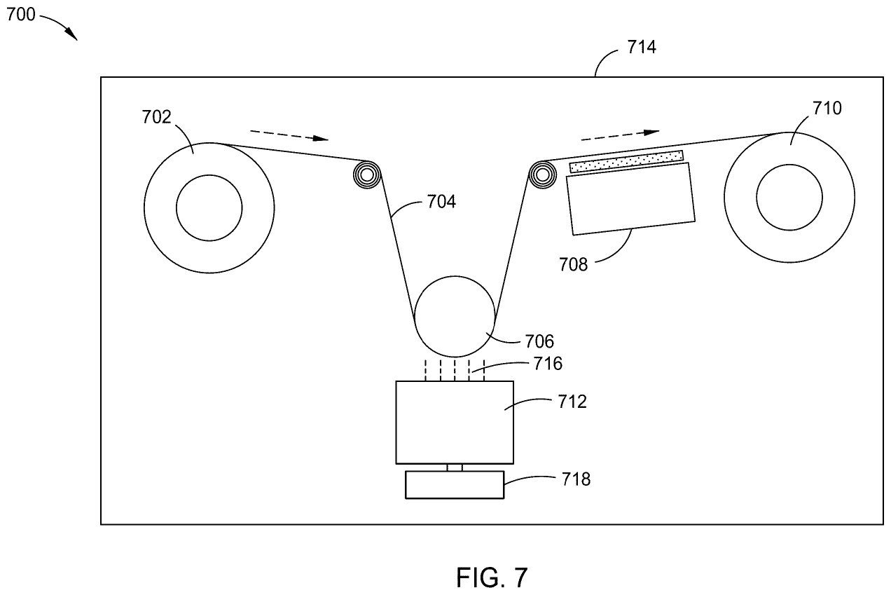

FIG. 7 illustrates a schematic cross-sectional view of one implementation of a roll-to-roll (R2R) material deposition system 700 incorporating a plasma-etching unit 708 in accordance with one or more implementations of the present disclosure. The plasma-etching unit 708 may be the plasma etching unit 200, 300 as described. The material deposition system 700 includes a substrate 704, one or more deposition sources 712, a curved drum 706, an incoming substrate roll 702, an outgoing substrate roll 710, and the plasma-etching unit 708. The one or more deposition sources 712 deposit lithium on the substrate 704 as the substrate 704 moves along a substrate travel path across the curved drum 706 continuously from the incoming substrate roll 702 to the outgoing substrate roll 710. The substrate may be or include the flexible carriers 110, 120 as described. The substrate 704 is conveyed along the substrate travel path over a curved surface of the drum 706 substantially facing the deposition source 712. After the lithium is deposited on the substrate 704 at the curved drum 706, an etching gas having one or more radical species, optionally mixed with a suitable inert gas, is generated at the plasma-etching unit 708 or at a remote chamber coupled to the plasma-etching unit 708. The etching gas may be oxygen (O₂), a mixture of O₂ with another gas, or any other suitable etching gas. The etching gas exits the plasma-etching unit 708 from a plasma-etching device outlet 716 substantially facing a surface of the exposed lithium deposited on the substrate 704. When the exposed lithium film is exposed to the etching gas via the plasma etching process, the etching gas reacts with any contaminants or residue disposed on the substrate 704, selectively removing any contaminants or residue from the surface of the substrate 704. The substrate 704 is not damaged during the plasma etching process. The plasma etching process may be performed in a vacuum chamber. In certain implementations, various process parameters, such as radio-frequency power, gas flow rate, pressure, and temperature, are modulated to achieve an efficient and selective plasma etching process. The etching time may be adjusted to remove the polymer contamination without causing substantial damage to the underlying lithium film. In some implementations, the exposed lithium is the lithium disposed on a substrate after the separation point of the substrate 704 from the deposition source 712, before the substrate 704 is removed from a high vacuum chamber 714.

In some embodiments, the plasma-etching unit 708 as described in FIG. 7 may be arranged substantially facing the surface of the substrate 704 disposed directly after the separation point of the substrate 704 from the curved drum 706, such that the substrate 704 can be cleaned and/or passivated before exiting the high vacuum chamber 714.

In some implementations, the material deposition system 700 may include an alteration crucible 718 situated at or substantially coupled to the deposition source 712. The alteration crucible 718 causes a phase change in a lithium or other suitable material. The deposition source 712 directs the altered material to the surface of the substrate 704 as it moves over the surface of the curved drum 706. The alteration crucible 718 may be an evaporation crucible for evaporating lithium into a lithium vapor, an alteration crucible 718 for producing molten lithium, or an alteration crucible for atomizing lithium. Implementation of a plasma-etching unit within an R2R system, as presented herein, ensures efficient and large-scale production of lithium film-based devices.

In some implementations, after plasma etching, the plasma-etching unit 708 is purged with an inert gas to remove residual etching byproducts. The inert gas may be nitrogen, or any other suitable inert gas. The plasma-etching unit 708 is then vented to atmospheric pressure, producing a clean and passivated lithium film on the substrate 704 that is prepared for further processing or device integration.

FIG. 8 illustrates an exemplary flow chart of a method 800 for plasma etching of a material in accordance with one or more implementations of the present disclosure. At operation 802, a deposition apparatus, for example, the material deposition system 700, deposits the material onto a substrate via an evaporation process. In some implementations, the material is a lithium film. In some implementations, the material is deposited onto a carrier film including a release layer, for example, a polyethylene terephthalate (PET) substrate having a polymer-based release layer formed thereon.

At operation 804, the lithium film is transferred from the carrier film to a flexible substrate stack, for example, the flexible substrate stack 130. The flexible substrate stack can be or include one of a current collector substrate and an anode film. The transfer process of operation 804 may be performed in a transfer system, for example, the transfer system 100. The transfer process can be a lamination process in which the lithium film is laminated on the anode film (if present) or directly onto the current collector. In some implementations, the foil is a copper foil. In some implementations, the laminating is performed using R2R lamination.

In operation 806, a plasma-etching device, for example, the plasma etching units 200, 300 subjects the material to a plasma etching process. The plasma etching process, which may be performed in a vacuum chamber, removes at least a portion of a release layer, for example, a polymer material, from a surface of the material. In one or more implementations, the plasma etching process removes a silicon containing polymer material. In some implementations, the plasma etching process uses an etching gas including oxygen. The plasma etching process also utilizes modulation of a set of process parameters to ensure controllable and selective ablation of the polymer material from the surface of the substrate to expose the lithium material layer. The process parameters include, but are not limited to, at least one of a radio-frequency power, a gas flow rate, a pressure value, and a temperature value. In some implementations, the plasma etching process removes the portion of the polymer in a non-damaging manner. In some implementations, the plasma etching process is performed at a low temperature value, such as at a temperature of less than 100° C., for example less than about 50° C., such as a temperature less than 20° C.

At operation 808, the plasma-etching unit 708 is purged with an inert gas. For example, after removal of the polymer material layer to expose the lithium material layer on the substrate, the plasma-etching unit 708 is purged with nitrogen to remove residual etching byproducts in the plasma-etching unit 708. At operation 810, the plasma-etching unit 708 is vented to an atmospheric pressure to produce a passivated surface on the material. The resulting substrate has a clean and passivated lithium film disposed thereon which is ready for further processing and device integration.

The previously described implementations of the present disclosure have many advantages including the following. Embodiments described herein are useful to improve the quality and throughput of substrates having lithium films formed thereon. The plasma etching methods described herein selectively remove the polymer film contamination from the surface of a lithium material layer disposed on a substrate. The resulting high purity lithium film enables improved performance. For example, the cleaned lithium film exhibits improved passivation properties which reduces the risk of device degradation. Additionally, the roll-to-roll lamination process enables efficient and large-scale production of lithium film-based devices. However, the present disclosure does not necessitate that all the advantageous features and all the advantages need to be incorporated into every implementation of the present disclosure.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results.

Accordingly, the previously described example implementations do not define or constrain the present disclosure. Other changes, substitutions, and alterations are also possible without departing from the spirit and scope of the present disclosure.

While the various steps in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple operations occurring concurrently or sequentially. Accordingly, the scope should not be considered limited to the specific arrangement of steps shown in a flowchart or diagram.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

When the word “approximately” or “about” are used, this term may mean that there may be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. For example, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112 (f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A flexible substrate processing system, comprising:
a pickup hub;
a supply hub;
a calendering unit comprising a first calender roller and a second calender roller, the calendering unit positioned downstream from the supply hub and upstream from the pickup hub; and
an atmospheric plasma etching unit having an interior volume, the pickup hub configured to rotate and assist in conveying a flexible substrate through the interior volume of the atmospheric plasma etching unit, the atmospheric plasma etching unit positioned downstream from the supply hub and upstream from the pickup hub, the atmospheric plasma etching unit comprising one or more plasma sources configured to generate and direct a plasma toward the flexible substrate when the flexible substrate is conveyed through the interior volume of the atmospheric plasma etching unit.

2. The flexible substrate processing system of claim 1, wherein the one or more plasma sources comprises a first plasma source and a second plasma source, the first plasma source positioned to direct a plasma to a first portion of the interior volume on a first side of the flexible substrate when the flexible substrate is conveyed through the interior volume of the atmospheric plasma etching unit and the second plasma source positioned to direct a plasma to a second portion of the interior volume on a second side of the flexible substrate opposite to the first side when the flexible substrate is conveyed through the interior volume of the atmospheric plasma etching unit.

3. The flexible substrate processing system of claim 1, wherein the atmospheric plasma etching unit is positioned downstream from the supply hub and upstream from the calendering unit.

4. The flexible substrate processing system of claim 1, wherein the atmospheric plasma etching unit is positioned downstream from the calendering unit and upstream from the pickup hub.

5. The flexible substrate processing system of claim 1, wherein the plasma is a non-equilibrium plasma generated at atmospheric pressure.

6. The flexible substrate processing system of claim 1, further comprising a pressure control system fluidly coupled with the interior volume.

7. The flexible substrate processing system of claim 6, wherein the pressure control system maintains pressure within the interior volume at an ambient pressure.

8. The flexible substrate processing system of claim 1, further comprising a passivation unit positioned downstream from the atmospheric plasma etching unit and upstream from the pickup hub.

9. A flexible substrate processing system for transferring a film from a substrate, comprising:
a plasma etching unit having an interior volume, the plasma etching unit, comprising:
one or more plasma sources configured to generate and direct a plasma toward a flexible substrate when the flexible substrate is conveyed through the interior volume of the plasma etching unit;
a system controller configured to cause the processing system to perform a process, comprising:
conveying a flexible carrier film stack from a supply hub toward a pickup hub, the flexible carrier film stack comprising a flexible carrier film having an alkali metal film formed thereover and a release layer disposed in between the flexible carrier film and the alkali metal film;
contacting the flexible carrier film stack with a flexible substrate film stack, wherein the alkali metal film contacts the flexible substrate film stack;
separating the flexible carrier film from the alkali metal film; and
exposing the alkali metal film to the plasma to remove at least a portion of the release layer from the alkali metal film.

10. The flexible substrate processing system of claim 9, wherein the plasma is a non-equilibrium plasma generated at atmospheric pressure.

11. The flexible substrate processing system of claim 9, wherein the process further comprises generating a plasma in the interior volume while maintaining the interior volume at an ambient pressure.

12. The flexible substrate processing system of claim 9, wherein the process further comprises passivating a surface of the alkali metal film after exposing the alkali metal film to the plasma.

13. The flexible substrate processing system of claim 9, wherein the flexible carrier film is formed from a polymer material and the alkali metal film is a lithium film.

14. The flexible substrate processing system of claim 9, wherein the plasma is formed from oxygen-containing gas and the release layer comprises a silicon-based polymer.

15. The flexible substrate processing system of claim 9, wherein the flexible substrate film stack comprises a current collector substrate, an anode film, or the anode film formed on the current collector substrate.

16. The flexible substrate processing system of claim 9, wherein contacting the flexible carrier film stack with the flexible substrate film stack comprises laminating the alkali metal film to the flexible substrate film stack.

17. A method for transferring a film from a substrate, comprising:
conveying a flexible carrier film stack from a supply hub toward a pickup hub, the flexible carrier film stack comprising a flexible carrier film having an alkali metal film formed thereover and a release layer disposed in between the flexible carrier film and the alkali metal film;
contacting the flexible carrier film stack with a flexible substrate film stack, wherein the alkali metal film contacts the flexible substrate film stack;
separating the flexible carrier film from the alkali metal film; and
exposing the alkali metal film to a plasma to remove at least a portion of the release layer from the alkali metal film.

18. The method of claim 17, wherein the plasma is a non-equilibrium plasma generated at atmospheric pressure.

19. The method of claim 17, further comprising generating the plasma in an interior volume of a plasma etching unit while maintaining the interior volume at an ambient pressure.

20. The method of claim 17, further comprising passivating a surface of the alkali metal film after exposing the alkali metal film to the plasma.
